(19) United States
(12) Patent Application Publication
(10) Pub. No.: US 2013/0169126 A1
(43) Pub. Date: Jul. 4, 2013

(54) INFORMATION PROCESSING DEVICE

(71) Applicant: Sony Corporation, Tokyo (JP)

(72) Inventors: Mamoru KATO, Nagano (JP); Kengo Masaoka, Nagano (JP); Soichi Tanaka, Kanagawa (JP); Yoshikazu Iriguchi, Nagano (JP)

(73) Assignee: Sony Corporation, Tokyo (JP)

(21) Appl. No.: 13/709,170

(22) Filed: Dec. 10, 2012

(30) Foreign Application Priority Data
Dec. 30, 2011 (CN) 201120570344.8

(51) Int. Cl. H05K 5/04

(52) U.S. Cl. CPC H05K 5/04
USPC 312/223.1

(57) ABSTRACT

The present disclosure relates to an information processing device which may include a housing made of metal. The housing may have a first surface and a mark formed on the first surface. The mark may be recessed relative to the first surface. At least one of a bottom surface and side surfaces of the mark may have different surface characteristics from that of the first surface. In the information processing device of the present disclosure, the mark is less prone to be abraded and is prone to be recognized. Further, the cost of the information processing device may be reduced by using the mark of the present disclosure.

The present application claims the benefit of priority to Chinese patent application No. 201120570344.8 titled “INFORMATION PROCESSING DEVICE”, filed with the Chinese State Intellectual Property Office on Dec. 30, 2011. The entire disclosure thereof is incorporated herein by reference.

### FIELD OF THE INVENTION

The present disclosure relates to an information processing device.

### BACKGROUND OF THE INVENTION

In information processing devices, such as a computer, a product mark is formed on a housing of the device and protruded outwardly from a surface of the housing so as to increase the recognizable degree of the product. However, since the product mark is protruded outwardly relative to the surface of the housing, the product mark is prone to be abraded or scratched, which affects the appearance of the product.

### SUMMARY OF THE INVENTION

A technical problem to be solved by the present disclosure is to provide an information processing device whose mark is less prone to be abraded.

Another technical problem to be solved by the present disclosure is to provide an information processing device whose mark is prone to be recognized.

A further technical problem to be solved by the present disclosure is to provide an information processing device whose mark has a low manufacturing cost.

According to one aspect of the present disclosure, an information processing device may include a housing made of metal, the housing having a first surface and a mark formed on the first surface, the mark being recessed relative to the first surface, wherein at least one of a bottom surface and side surfaces of the mark may have different surface characteristics from that of the first surface.

Preferably, light reflectivity of at lease one of the bottom surface and the side surfaces may be higher than that of the first surface.

Preferably, the first surface may have an anode oxidation layer. The side surfaces may be cut processed metal surfaces. The bottom surface may have an anode oxidation layer.

Preferably, the bottom surface may be a cut processed metal surface. The side surfaces may have an anode oxidation layer.

Preferably, both of the bottom surface and the side surfaces may be cut processed metal surfaces.

Preferably, the information processing device may include a computer, a mobile phone, a CD player, a DVD player, a MP3 player, a MP4 player, a MP5 player, a palm game player, a photo camera, a video camera and a television.

Preferably, the mark may indicate a product name of the information processing device.

Preferably, the bottom surface and side surfaces may be formed in a trapezoidal shape.

The present disclosure has the following advantages.

In the information processing device of the present disclosure, the mark for indicating the product name may be recessed relative to the first surface of the housing. Therefore, the mark is less prone to be abraded or scratched. Even if the information processing device has been used for a long time, the mark may be recognized easily. Further, at least one of a bottom surface and side surfaces of the mark may have different surface characteristics from that of the first surface. For example, the first surface of the housing may have an anode oxidation layer, at least one of a bottom surface and side surfaces of the mark may be cut processed metal surface. Therefore, light reflectivity of the metal surface of the mark may be higher than that of the first surface of the housing, thereby increasing the contrast between the mark and the surface of the housing and thus increasing the recognizable degree of the mark.

Further, by using the mark of the present disclosure, since the mark, which is formed separately and is adhered onto a product surface, in the prior art may be omitted, a cost for forming the product mark is reduced, thereby reducing the cost of the information processing device.

Further, the mark having the above characteristics may be applied to various information processing devices, for example, including but not limited to a computer, a mobile phone, a CD player, a DVD player, a MP3 player, a MP4 player, a MP5 player, a palm game player, a photo camera, a video camera, a television and so on.

### BRIEF DESCRIPTION OF THE DRAWINGS

The above and other features and advantages of the present disclosure will be better understood from the following description with reference to the drawings in which:

FIG. 1 is a perspective view of an example of an information processing device according to the present disclosure;

FIG. 2 is a top view of an example of the information processing device according to the present disclosure;

FIG. 3 is a schematic perspective view of a mark on the information processing device of the present disclosure;

FIG. 4 is a partial enlarged top view of the mark shown in FIG. 3;

FIG. 5 is a sectional view taken along line A-A in FIG. 4, illustrating a cross section of the mark after anode oxidation treatment;

FIG. 6, similar to FIG. 5, is a sectional view illustrating a cross section of the mark according to a first embodiment;

FIG. 7, similar to FIG. 5, is a sectional view illustrating a cross section of the mark according to a second embodiment; and

FIG. 8, similar to FIG. 5, is a sectional view illustrating a cross section of the mark according to a third embodiment.

### DETAILED DESCRIPTION OF THE EMBODIMENTS

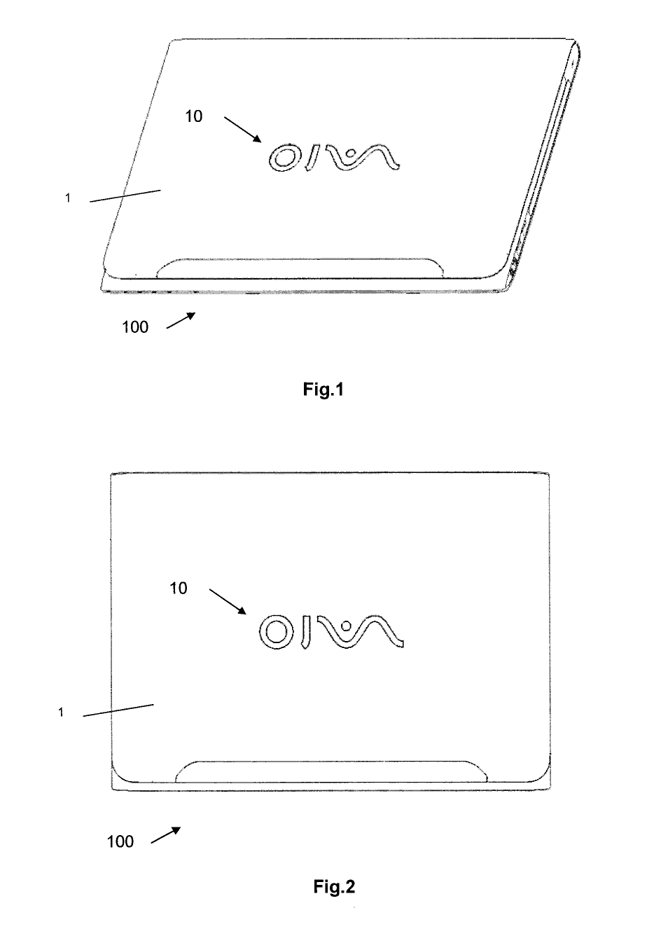

Various embodiments of the information processing device of the present disclosure will be described with reference to FIGS. 1 to 8.

In FIGS. 1 to 8, the structure of the mark on the information processing device of the present disclosure is described by taking a portable computer for an example. The person skilled in the art should understand that, the mark of the present disclosure may be applied to various information processing devices, including but not limited to a computer, a mobile phone, a CD player, a DVD player, a MP3 player, a MP4 player, a MP5 player, a palm game player, a photo camera, a video camera, a television and so on. In addition, in the examples shown in the drawings, the mark is used to indicate a product name of the information processing device. However, the person skilled in the art should understand that, the mark is not limited to indicate the product name, but may indicate other information, such as a trademark, a model type, etc.

The basic structure of the information processing device of the present disclosure will be described briefly hereinafter with reference to FIGS. 1 to 3.

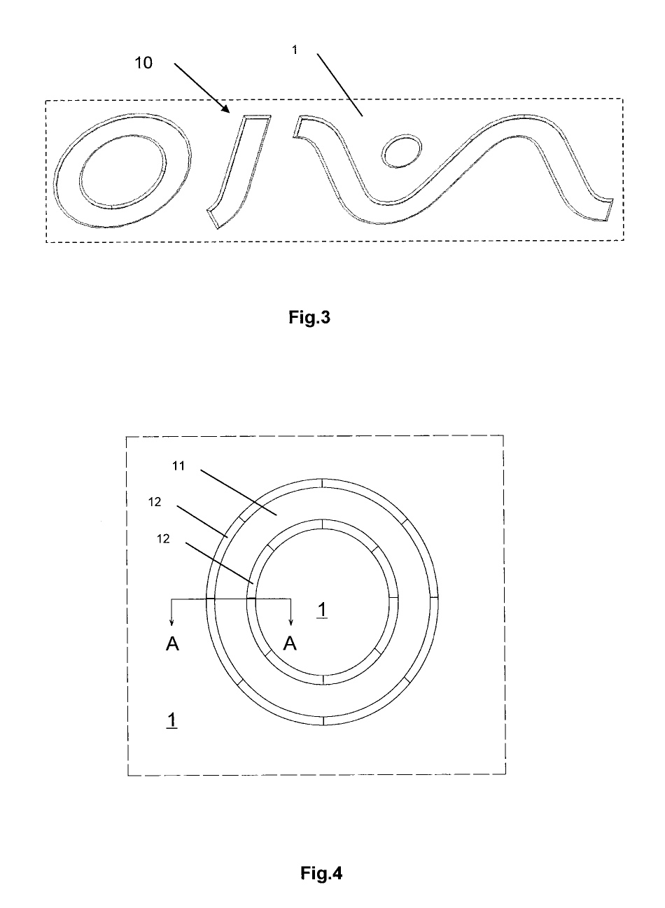

As shown in FIGS. 1 to 3, an information processing device 100, such as a portable computer, may include a housing made of metal such as aluminum, aluminum alloy, magnesium, magnesium alloy or other metal materials. The housing may have a first surface 1 and a mark 10 formed on the first surface 1 of the housing. As shown clearly in FIG. 3, the mark 10 is recessed relative to the first surface 1 of the housing. The mark 10 may be integrally formed in the metal housing by for example a pressing process.

FIG. 4 is a partial enlarged view showing a top view of a part of the mark 10. As shown in the figure, the mark 10 may include a bottom surface 11 and side surfaces 12.

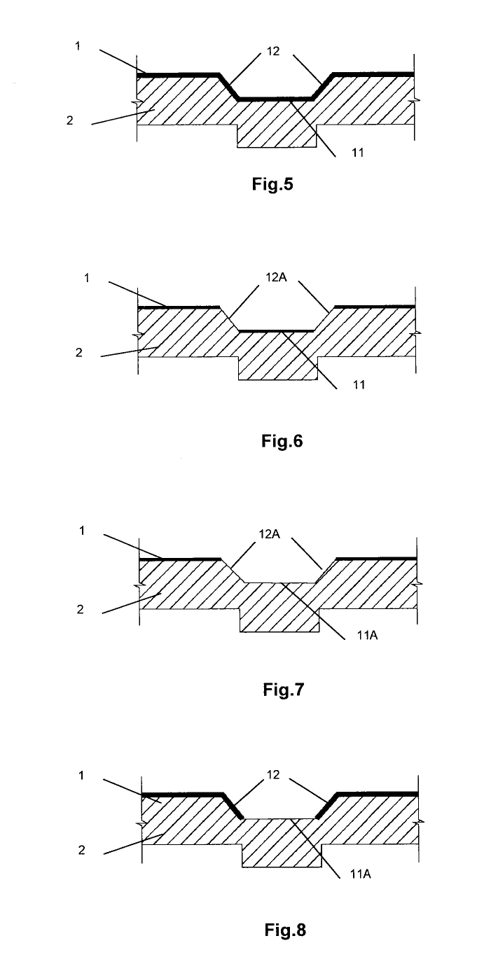

As shown in FIG. 5, the first surface 1 of the housing, the bottom surface 11 and side surfaces 12 of the mark 10 may be subject to an anode oxidation treatment to form an anode oxidation layer thereon, thereby improving the abrasive resistance, hardness and corrosion resistance of the material. Since the mark 10 is recessed relative to the first surface 1 of the housing and is subject to the anode oxidation treatment, the mark 10 is less prone to be abraded and has better physical and chemical characteristics.

In embodiments of the present disclosure shown in FIGS. 6 to 8, at least a part of surfaces of the mark 10 may have different surface characteristics from that of the first surface 1 of the housing. Specifically, at least one of the bottom surface and side surfaces of the mark 10 may have different surface characteristics from that of the first surface 1 of the housing. For example, light reflectivity of at lease one of the bottom surface and the side surfaces may be higher than that of the first surface.

Specifically, in the first embodiment shown in FIG. 6, the anode oxidation layer on the side surfaces 12 of the mark 10 shown in FIG. 5 may be cut to expose the natural metal material of the metal housing through a cut process, for example a hard metal cut process or a diamond cut process. In other words, in the first embodiment shown in FIG. 6, the first surface 1 of the housing has an anode oxidation layer, the bottom 11 of the mark 10 has an anode oxidation layer, and the side surfaces 12A of the mark 10 are cut processed metal surfaces. In this way, the side surfaces 12A of the mark 10 will have higher light reflectivity than that of the first surface 1 and the bottom surface 11, and may show a strong metallic texture. As a result, the mark is less prone to be abraded while having better recognizable degree.

In the second embodiment shown in FIG. 7, the anode oxidation layer on the side surfaces 12 and the bottom surface 11 of the mark 10 shown in FIG. 5 may be cut to expose the natural metal material of the metal housing through a cut process, for example a hard metal cut process or a diamond cut process. In other words, in the second embodiment shown in FIG. 7, the first surface 1 of the housing has an anode oxidation layer, and the bottom 11A and the side surfaces 12A of the mark 10 are cut processed metal surfaces. Thus, the bottom surface 11A and the side surfaces 12A of the mark 10 will have higher light reflectivity than that of the first surface 1, and may show a strong metallic texture. As a result, the mark is less prone to be abraded while having better recognizable degree.

In the third embodiment shown in FIG. 8, the anode oxidation layer on the bottom surface 11 of the mark 10 shown in FIG. 5 may be cut to expose the natural metal material of the metal housing through a cut process, for example a hard metal cut process or a diamond cut process. In other words, in the third embodiment shown in FIG. 8, the first surface 1 of the housing has an anode oxidation layer, the side surfaces 12A of the mark 10 has an anode oxidation layer, and the bottom 11A of the mark 10 is cut processed metal surface. Thus, the bottom surface 11A of the mark 10 will have higher light reflectivity than that of the first surface 1 and the side surfaces 12A, and may show a strong metallic texture. As a result, the mark is less prone to be abraded while having better recognizable degree.

In the embodiments shown in FIGS. 6 to 8, the bottom surface 11 or 11A and the side surfaces 12 or 12A of the mark 10 are formed in a trapezoidal shape, that is, the side surfaces 12 or 12A are inclined relative to the bottom surface 11 or 11A. However, depending on different configurations of the design of the mark 10, the side surfaces 12 or 12A may also be vertical to the bottom surface 11 or 11A so as to form a rectangular shape.

Various embodiments of the present disclosure have been described in detail herein. It should be understood that the present disclosure is not limited to the above described and illustrated embodiments, and other modifications and variations to the present disclosure may be made by the person skilled in the art without departing from the principle and scope of the present disclosure. These modifications and variations are deemed to fall into the protection scope of the present disclosure. Further, all of the components described herein may be substituted by other technical equivalent components.

What is claimed is:

1. An information processing device comprising a housing made of metal, the housing having a first surface and a mark formed on the first surface, the mark being recessed relative to the first surface,
wherein at least one of a bottom surface and side surfaces of the mark has different surface characteristics from that of the first surface.

2. The information processing device according to claim 1, wherein light reflectivity of at lease one of the bottom surface and the side surfaces is higher than that of the first surface.

3. The information processing device according to claim 1, wherein the first surface has an anode oxidation layer.

4. The information processing device according to claim 1, wherein the side surfaces are cut processed metal surfaces.

5. The information processing device according to claim 4, wherein the bottom surface has an anode oxidation layer.

6. The information processing device according to claim 1, wherein the bottom surface is a cut processed metal surface.

7. The information processing device according to claim 6, wherein the side surfaces have an anode oxidation layer.

8. The information processing device according to claim 1, wherein both of the bottom surface and the side surfaces are cut processed metal surfaces.

9. The information processing device according to claim 1, wherein the information processing device comprises a computer, a mobile phone, a CD player, a DVD player, a MP3 player, a MP4 player, a MP5 player, a palm game player, a photo camera, a video camera and a television.

10. The information processing device according to claim 1, wherein the mark indicates a product name of the information processing device.

11. The information processing device according to claim 1, wherein the bottom surface and side surfaces are formed in a trapezoidal shape.

12. The information processing device according to claim 2, wherein the first surface has an anode oxidation layer.

13. The information processing device according to claim 2, wherein the side surfaces are cut processed metal surfaces.

14. The information processing device according to claim 13, wherein the bottom surface has an anode oxidation layer.

15. The information processing device according to claim 2, wherein the bottom surface is a cut processed metal surface.

16. The information processing device according to claim 15, wherein the side surfaces have an anode oxidation layer.

17. The information processing device according to claim 2, wherein both of the bottom surface and the side surfaces are cut processed metal surfaces.
